(19) United States
(12) Patent Application Publication
(10) Pub. No.: US 2026/0075767 A1
(43) Pub. Date: Mar. 12, 2026

(54) Fabrication of Wicking Structures and Multiphase Devices for Heat-Transfer

(71) Applicant: Fabric8Labs, Inc., San Diego, CA (US)

(72) Inventors: Joseph Madril, San Diego, CA (US); Ian Winfield, Oceanside, CA (US); Charles Biset, San Diego, CA (US); Douglas Castro, San Diego, CA (US); Guillermo Romero, Phoenix, AZ (US); Timothy Ouradnik, San Diego, CA (US)

(21) Appl. No.: 19/308,622

(22) Filed: Aug. 25, 2025

Related U.S. Application Data
(60) Provisional application No. 63/694,053, filed on Sep. 12, 2024.
(60) Provisional application No. 63/695,162, filed on Sep. 16, 2024.
(60) Provisional application No. 63/696,759, filed on Sep. 19, 2024.
(60) Provisional application No. 63/697,403, filed on Sep. 20, 2024.
(60) Provisional application No. 63/697,993, filed on Sep. 23, 2024.
(60) Provisional application No. 63/725,483, filed on Nov. 26, 2024.

(51) Int. Cl. H05K 7/20; B33Y 10/00; B33Y 80/00; C25D 1/00

(52) U.S. Cl. CPC H05K 7/20336; B33Y 10/00; B33Y 80/00; C25D 1/003; H05K 7/20381

(57) ABSTRACT

A method of fabricating a multiphase heat exchanger for thermal coupling to a heat source is provided. The method includes submerging a build plate having a deposition surface into an electrolyte, the deposition surface comprising at least one of an evaporator base, a condenser base, or a liquid-return base. A printhead comprising pixelated electrodes and electrode-array drivers is submerged proximate to the deposition surface. A subset of the pixelated electrodes is selectively activated to generate an ionic flow through the electrolyte between the electrode subset and a portion of the deposition surface, thereby electrochemically depositing wicking structures on the base surface. Any two adjacent wicking structures positioned on the evaporator base are spaced apart by an average pitch selected to maintain a heat-transfer fluid, in a liquid phase, in contact with the evaporator base during operation of the multiphase heat exchanger.

### CROSS-REFERENCE TO RELATED APPLICATIONS

This application claims the benefit under 35 U.S.C. § 119 (e) of U.S. Provisional Patent Application 63/694,053 (Docket No. F8L-044-PRO), filed on 2024 Sep. 12, U.S. Provisional Patent Application 63/697,993 (Docket No. F8L-026-PRO) filed on 2024 Sep. 23, U.S. Provisional Patent Application 63/725,483 (Docket No. F8L-048-PRO2) filed on 2024 Nov. 26, U.S. Provisional Patent Application 63/695,162, (Docket No. F8L-045-PRO) filed on 2024 Sep. 16, U.S. Provisional Patent Application 63/696,759, (Docket No. F8L-046-PRO), filed on 2024 Sep. 19, and U.S. Provisional Patent Application 63/697,403 (Docket No. F8L-047-PRO), filed on 2024 Sep. 20, all of which are incorporated herein by reference in their entirety for all purposes.

### BACKGROUND

Rising power densities in high-performance computing systems, advanced semiconductor devices, power electronics, and other applications push the cooling requirements beyond conventional air-cooling and, in some instances, single-phase liquid cooling solutions. As a result, multiphase heat exchangers have emerged to provide higher heat flux rates while maintaining compact form factors. In such heat exchangers, heat-transfer fluids change phase (e.g., liquid-gas) to provide additional heat transfer capabilities and fluid mobility within these heat exchangers.

Conventional multiphase heat exchangers suffer from several technical limitations, e.g., instability during flow boiling within microchannels. This can lead to local “dry-out” conditions and a corresponding drop in heat flux. Efforts to design new wicking structures to address these “dry-out” conditions have been limited to fabrication techniques, such as powder-based sintering or foamed metal techniques. Specifically, the resulting wicking structures suffer from poor uniformity, weak thermal contact with their base plates, and other issues. Furthermore, these manufacturing techniques are constrained in their ability to fabricate tailored, high-aspect-ratio, or geometrically complex wicking features. As a result, these limitations hinder the ability to optimize fluid distribution, control capillary-driven flow, and mitigate vapor entrapment near heated surfaces. Similar issues also appear on the condenser sides of the conventional multiphase heat exchangers.

Accordingly, there is a need for new configurations of multiphase heat exchangers and fabrication techniques (e.g., electrochemical additive manufacturing (ECAM)) that enable these configurations.

### SUMMARY

A multiphase heat exchanger includes an evaporator, a condenser, and a liquid-return portion extending between the evaporator and the condenser, such that microstructured wicking structures are electrochemically integrated into one or more of these components. In an evaporator, the wicking structures promote capillary-driven liquid transport and assist in displacing vapor bubbles from the evaporator to improve two-phase cooling performance. By tailoring the geometry, location, and density of the wicking features, localized “dryouts” are mitigated thereby ensuring efficient heat transfer. Wicking structures may be also positioned along sidewalls, at channel bases, or on fin surfaces to maintain fluid distribution and enhance phase-change efficiency. Electrochemical additive manufacturing (ECAM) enables precise, layer-by-layer fabrication of these structures, allowing customization for different flow regimes and heat flux profiles. The resulting device supports higher thermal loads, improved reliability, and consistent manufacturing for advanced heat transfer/cooling applications.

Clause 1. A multiphase heat exchanger for thermal coupling to a heat source, the multiphase heat exchanger comprising: an evaporator base comprising a heat-source interface for thermal coupling to the heat source; a condenser base spaced away from the evaporator base by a cavity configured to contain a heat-transfer fluid, the condenser base comprising an external heat-release interface; a liquid-return base extending between the evaporator base and the condenser base; and wicking structures electrochemically deposited on a base surface formed by at least one of (a) the evaporator base forming an evaporator, (b) the condenser base forming a condenser, or (c) the liquid-return base forming a liquid-return portion, wherein: the wicking structures protrude into the cavity away from the base surface, the evaporator is configured to evaporate the heat-transfer fluid, from a liquid phase to a gas phase, upon receiving heat from the heat source through the heat-source interface, the condenser is configured to condense the heat-transfer fluid, from the gas phase to the liquid phase, by releasing heat through the external heat-release interface, the liquid-return portion is configured to return the heat-transfer fluid, in the liquid phase, from the condenser to the evaporator, and any two adjacent ones of the wicking structures, attached to the evaporator base, are spaced apart by an average pitch selected to maintain the heat-transfer fluid, in the liquid phase, in contact with at least a part of the evaporator base during operation of the multiphase heat exchanger.

Clause 2. The multiphase heat exchanger of clause 1, wherein the wicking structures, attached to the condenser base, are configured to facilitate capillary pumping of the heat-transfer fluid, in the liquid phase, away from the condenser base.

Clause 3. The multiphase heat exchanger of clause 1, wherein the wicking structures, attached to the liquid-return base, vary in size or pitch along a direction to achieve one or more of (a) to compensate for changes in a gravitational or capillary head in an intended operational environment and (b) to compensate for differences in anticipated heat loads in the intended operational environment

Clause 4. The multiphase heat exchanger of clause 1, wherein: the wicking structures are electrochemically deposited on both the evaporator base and the liquid-return base, and the pitch of the wicking structures electrochemically deposited on the evaporator base is greater than the pitch of the wicking structures electrochemically deposited on the liquid-return base.

Clause 5. The multiphase heat exchanger of clause 1, wherein the evaporator base and the condenser base are laterally aligned.

Clause 6. The multiphase heat exchanger of clause 1, wherein the evaporator base and the condenser base are laterally offset.

Clause 7. The multiphase heat exchanger of clause 1, further comprising one or more bridging portions, extending through the cavity between and connected to each of the evaporator base and the condenser base, wherein the one or more bridging portions are parts of the liquid-return portion.

Clause 8. The multiphase heat exchanger of clause 7, wherein the wicking structures are electrochemically deposited on the one or more bridging portions.

Clause 9. The multiphase heat exchanger of clause 7, wherein the one or more bridging portions are electrochemically deposited on the evaporator base or the condenser base.

Clause 10. The multiphase heat exchanger of clause 1, wherein the evaporator base or the condenser base is electrochemically deposited.

Clause 11. The multiphase heat exchanger of clause 1, wherein one or of the wicking structures are a 1-dimensional column comprising a base growth rooted to at least one of the evaporator base, the condenser base, and the liquid-return base by electrochemical deposition.

Clause 12. The multiphase heat exchanger of clause 11, wherein: the wicking structures are arranged into a set of rows, and the wicking structures in two adjacent rows in the set of rows are offset relative to each other forming a straight channel for the heat-transfer fluid.

Clause 13. The multiphase heat exchanger of clause 1, wherein one or more of the wicking structures are a 2-dimensional (2D) wall comprising a base growth rooted to the base surface by electrochemical deposition.

Clause 14. The multiphase heat exchanger of clause 1, wherein the wicking structures are configured to direct the heat-transfer fluid in all three directions as the heat-transfer fluid is proximate to the base surface.

Clause 15. The multiphase heat exchanger of clause 14, wherein: one or more of the wicking structures comprise a base and an overhang, the base is electrochemically deposited on the base surface, positioned between the overhang and the base surface, and supports the overhang relative to the base surface, the overhang protrudes beyond a footprint of the base thereby forming a lower cavity proximate to the base surface, the overhang of two adjacent ones of the wicking structures are spaced, forming an upper cavity, fluidically coupled with the lower cavity by an opening.

Clause 16. The multiphase heat exchanger of clause 1, wherein the wicking structures have a height (H) of 30-3,000 micrometers.

Clause 17. The multiphase heat exchanger of clause 1, wherein the wicking structures have a thickness (T) of 30-200 micrometers.

Clause 18. The multiphase heat exchanger of clause 1, wherein the wicking structures have an average pitch (P) of 50-1,0000 micrometers.

Clause 19. The multiphase heat exchanger of clause 1, wherein: the evaporator base and the condenser base define a liquid-flow direction, and a pitch (P) of the wicking structures changes along the liquid-flow direction.

Clause 20. The multiphase heat exchanger of clause 19, wherein the pitch (P) of the wicking structures decreases in the liquid-return portion along a flow direction of the heat-transfer fluid.

Clause 21. The multiphase heat exchanger of clause 1, wherein the wicking structures have a nucleation point density of at least 100/mm2 based on a surface area of the base surface, at least in the evaporator base.

Clause 22. The multiphase heat exchanger of clause 1, wherein the wicking structures have an electrochemically-deposited base and one or more structures bonded to the electrochemically-deposited base, and selected from the group consisting of mesh, woven fabric, and sintered powder.

Clause 23. The multiphase heat exchanger of clause 1, wherein one or more of the wicking structures are selected from the group consisting of a composite wick, a lattice, a TPMS structure, a uniform and composite structure, a composite gyroid, a body-centered-cubic (BCC), and a composite body-centered-cubic (BCC).

Clause 24. The multiphase heat exchanger of clause 1, further comprising the heat-transfer fluid provided in the cavity.

Clause 25. The multiphase heat exchanger of clause 21, wherein the heat-transfer fluid is selected from the group consisting of a hydrofluorocarbon refrigerant, a hydrocarbon refrigerant, a chlorofluorocarbon refrigerant, an ammonia refrigerant, and a carbon dioxide refrigerant.

Clause 26. The multiphase heat exchanger of clause 1, further comprising an external heat-transferring unit, thermally coupled to the condenser base.

Clause 27. The multiphase heat exchanger of clause 26, wherein the external heat-transferring unit is electrochemically deposited on the condenser base.

Clause 28. The multiphase heat exchanger of clause 26, wherein the external heat-transferring unit and the condenser base are formed from different materials.

Clause 29. A method of fabricating a multiphase heat exchanger for use on a heat source comprising a heat-transferring surface using electrochemical additive manufacturing (ECAM), the method comprising: submerging a build plate comprising a deposition surface into an electrolyte, wherein the build plate comprises a base surface formed by at least one of (a) an evaporator base, (b) a condenser base, or (c) a liquid-return base; submerging a printhead into the electrolyte proximate to the deposition surface, the printhead comprises a set of pixelated electrodes and electrode-array drivers; and selectively activating an electrode subset from the set of pixelated electrodes using the electrode-array drivers thereby generating an ionic flow through the electrolyte between the electrode subset and a portion of the deposition surface aligned with the electrode subset and thereby electrochemically depositing wicking structures on the base surface of the build plate, wherein any two adjacent ones of the wicking structures, attached to the evaporator base, are spaced apart by an average pitch selected to maintain a heat-transfer fluid, in a liquid phase, in contact with the at least one of the evaporator base during operation of the multiphase heat exchanger.

Clause 30. The method of clause 29, wherein the base surface is formed by the evaporator base such that depositing the wicking structures on the base surface forms an evaporator configured to evaporate the heat-transfer fluid, from a liquid phase to a gas phase, upon receiving heat from the heat source.

Clause 31. The method of clause 30, wherein the base surface is formed by the condenser base such that depositing the wicking structures on the base surface forms a condenser configured to condense the heat-transfer fluid, from the gas phase to the liquid phase.

Clause 32. The method of clause 31, wherein the base surface is formed by the liquid-return base such that depositing the wicking structures on the base surface forms a liquid-return portion is configured to return the heat-transfer fluid, in the liquid phase, from the condenser to the evaporator, and

Clause 33. The method of clause 29, further comprising thermally coupling the evaporator base to the heat-transferring surface of the heat source.

Clause 34. The method of clause 33, wherein thermally coupling the evaporator base to the heat-transferring surface of the heat source comprises positioning a thermal interface between the evaporator base and the heat-transferring surface.

Clause 35. The method of clause 29, wherein the build plate comprises the heat source.

Clause 36. The method of clause 35, wherein the heat source is selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC).

Clause 37. The method of clause 35, further comprising, prior to submerging the build plate into the electrolyte, method comprises forming a conductive seed layer on the build plate.

Clause 38. The method of clause 37, wherein forming the conductive seed layer on the build plate comprises one or more techniques selected from the group consisting of sputtering, electroless electroplating, and thermal bonding.

Clause 39. The method of clause 29, further comprising, prior to selectively activating the electrode subset, designing a shape of the multiphase heat exchanger and developing a set of deposition maps corresponding to the shape of the multiphase heat exchanger, wherein the electrode subset is activated based on a deposition map in the set of deposition maps.

Clause 40. The method of clause 29, further comprising, after submerging the build plate and submerging the printhead and before selectively activating the electrode subset, registering a horizontal position of the build plate relative to the printhead using a mapping process and based on a shape of the build plate.

Clause 41. The method of clause 29, further comprising replacing the electrolyte between the printhead and the build plate.

Clause 42. The method of clause 41, wherein the electrolyte is replaced with the electrolyte having a different composition.

Clause 43. The method of clause 29, further comprising attaching an external heat-transferring unit to a condenser base.

Clause 44. The method of clause 43, wherein attaching the external heat-transferring unit to the condenser base comprises: submerging the condenser base into the electrolyte, and selectively activating the electrode subset from the set of pixelated electrodes using the electrode-array drivers thereby electrochemically depositing the external heat-transferring unit comprising heat-transferring structures extending away from the condenser base in a direction opposite of the evaporator base.

Clause 45. The method of clause 29, wherein: the condenser base is spaced away from the evaporator base by a cavity, the method further comprises filing the cavity with the heat-transfer fluid selected from the group consisting of a hydrofluorocarbon refrigerant, a hydrocarbon refrigerant, a chlorofluorocarbon refrigerant, an ammonia refrigerant, and a carbon dioxide refrigerant.

Clause 46. The method of clause 29, wherein one or more of the wicking structures are selected from the group consisting of a composite wick, a lattice, a TPMS structure, a uniform and composite structure, a composite gyroid, a body-centered-cubic (BCC), and a composite body-centered-cubic (BCC).

Clause 47. The method of clause 29, wherein the wicking structures, attached to the condenser base, are configured to enhance capillary pumping of the heat-transfer fluid, in the liquid phase, away from the condenser base.

Clause 48. The method of clause 29, wherein the wicking structures, attached to the liquid-return base, vary in size or pitch along a direction from the condenser base to the evaporator base to compensate for changes in a gravitational or capillary head.

These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, and methods. These drawings in no way limit any changes in form and detail that may be made by one skilled in art without departing from the spirit and scope of the disclosed implementations.

FIG. 1A is a schematic cross-sectional view of a multiphase heat exchanger thermally, comprising an evaporator, thermally coupled to a heat source, and a condenser, thermally coupled to an external heat-transferring unit, such that the evaporator and condenser are laterally aligned and comprising wicking structures, in accordance with some examples.

FIG. 1B is a schematic cross-sectional view of a multiphase heat exchanger similar to the one in FIG. 1A, with the evaporator and condenser being laterally offset relative to each other, in accordance with some examples.

FIG. 1C is a schematic cross-sectional view of a multiphase heat exchanger similar to the one in FIG. 1A, further comprising bridging portions extending between the evaporator and condenser and supporting additional wicking structures, in accordance with some examples.

FIG. 1D is a schematic cross-sectional view of a multiphase heat exchanger similar to the one in FIG. 1C, in which the bridging portions are substituted with one or more added bridges, inserted into the mating supporting on the evaporator base 151, in accordance with some examples.

FIGS. 1E-1J are schematic cross-sectional views of different stages during the fabrication of the multiphase heat exchanger in FIG. 1D, in accordance with some examples.

FIG. 2A is a top schematic view of wicking structures in the form of square pillars extending from and electrochemically deposited onto the base surface, in accordance with some examples.

FIG. 2B is a side cross-sectional view of the wicking structures in FIG. 2A, in accordance with some examples.

FIGS. 2C and 2D are top schematic views of two additional examples of wicking structures.

FIG. 2E is a perspective view of a wicking structure with ribbed walls, in accordance with some examples.

FIG. 3A is a schematic perspective view of wicking structures forming tortuous paths for heat-transfer fluid, in accordance with some examples.

FIG. 3B illustrates two cross-sectional views of the wicking structures in FIG. 3A to illustrate some aspects of the tortuous paths, in accordance with some examples.

FIGS. 4A-4C are schematic side views of different examples of wicking structures electrochemically formed on protrusions.

FIG. 5A is a method of fabricating a multiphase heat exchanger comprising wicking structures electrochemically deposited on a base structure, in accordance with some examples.

FIGS. 5B-5G are schematic illustrations of different stages of fabricating a multiphase heat exchanger, in accordance with some examples.

FIG. 6A is a schematic illustration of an ECAM system for fabricating heat exchangers, in accordance with some examples.

FIG. 6B is the top view of a printhead comprising a set of pixelated electrodes, in accordance with some examples.

FIG. 6C is a schematic expanded view of a portion of the ECAM system (in FIG. 6A) illustrating electrolyte between the printhead and build plate, in accordance with some examples.

FIG. 6D is a schematic block diagram illustrating different components of the electrolyte, in accordance with some examples.

### DETAILED DESCRIPTION

### Introduction

Efficient thermal management is a fundamental challenge in advanced microprocessors, power electronics, and other systems with high localized heat generation. As power densities increase, conventional air-cooled heat exchangers are replaced with liquid-cooled heat exchangers and multiphase heat exchangers. A multiphase heat exchanger may be also referred to as a two-phase heat exchanger as the heat fluid may be present as a combination of both liquid and gas, depending on the location and operating state of the heat exchanger. However, the widespread deployment of multiphase heat exchangers has been hindered by manufacturability challenges, e.g., limiting the configuration of wicking structures and other components of these heat exchangers. For example, many conventional heat exchangers are still manufactured by skiving a copper baseplate to form a set of parallel cooling fins (e.g., about 250 micrometers thick with a spacing/channel width of about 500 micrometers and a height of about 3 millimeters). Such cooling fins/microchannels are uniform in design and layout, lacking adaptability for spatially varying thermal loads and, more specifically, managing gas and vapor flows in complex multiphase environments. As a result, attempts to operate these structures, e.g., in evaporators of multiphase heat exchangers, may cause local “dryouts”, where liquid supply to the portions of the cooled surface is interrupted sharply reducing the heat transfer in these areas.

Beyond flow instability, significant shortcomings also arise from current approaches to integrating porous wicking structures into multiphase heat exchangers. For example, sintered powders or bonded metal foams often have limited adhesion/thermal transfer to the underlying substrate (affecting mechanical robustness and heat transfer). Furthermore, these approaches often produce randomly distributed pore sizes and geometries, resulting in inconsistent capillary action and thermal performance within the same heat exchanger or among heat exchangers. Finally, these approaches do not allow any significant customization of wicking structures and other components to accommodate specific heating profiles and/or fluidic flows. For example, a heat source may have a non-uniform heat generation across its interface with a heat exchanger. Furthermore, the relative positions of the evaporators and condensers in multiphase heat exchangers may cause variability in heat transfer capabilities.

Electrochemical additive manufacturing (ECAM) provides novel approaches for fabricating multiphase heat exchangers and, in particular, wicking structures of such heat exchangers. ECAM involves layer-by-layer electrodeposition of various metals by precisely controlling the footprint of each deposited layer. It allows the fabricating of high-aspect-ratio structures, non-linear structures, and variable design structures (at different locations) thereby specifically accommodating various requirements of the multiphase heat transfer. For example, wicks can be fabricated directly on sidewalls, fin tops, channel floors, or other non-planar surfaces to match the thermal and flow demands of a given application.

### Multi-Phase Heat Exchangers

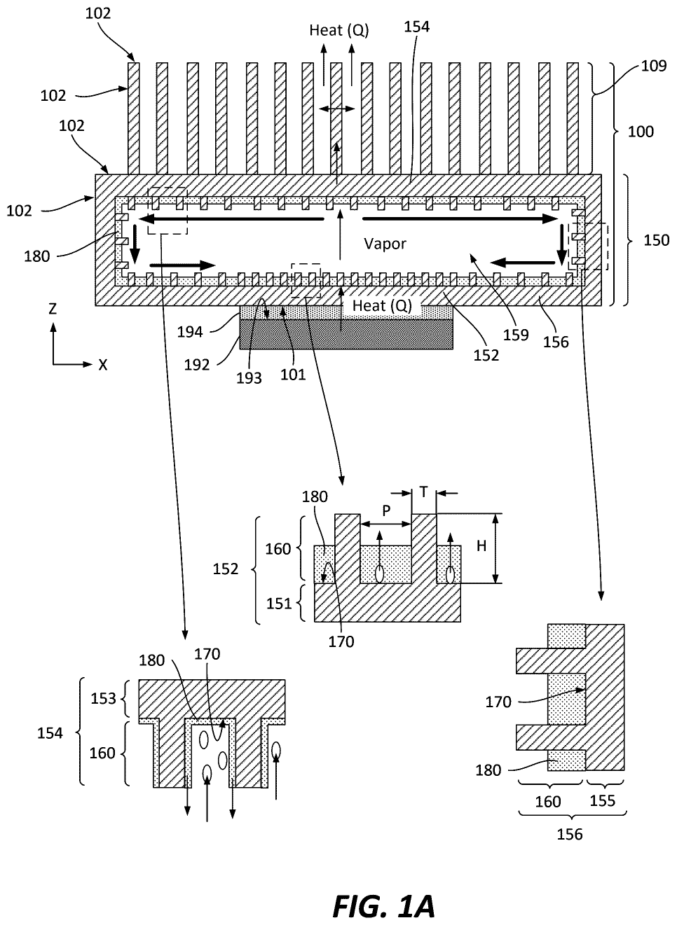

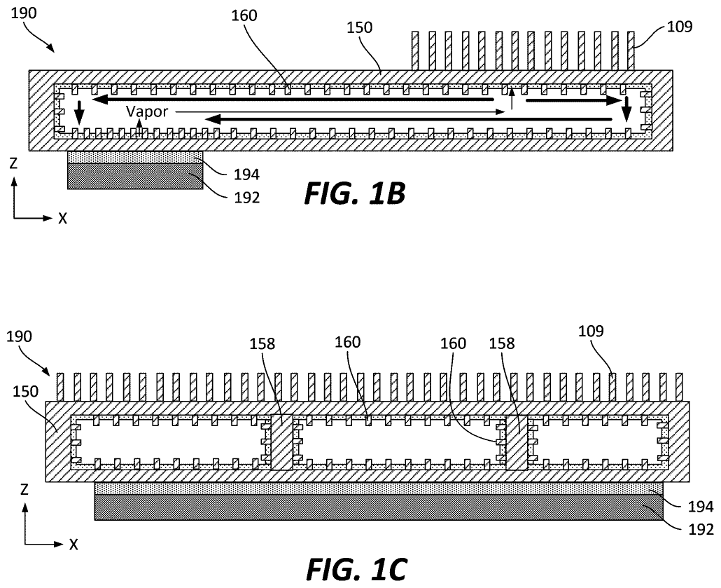

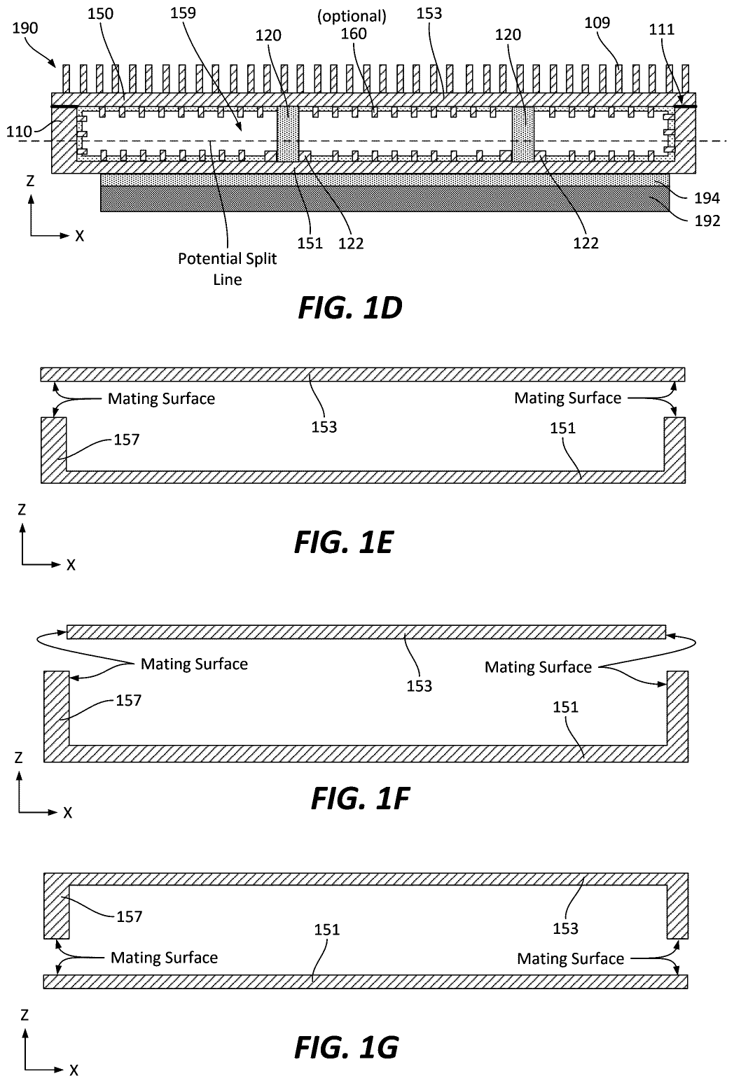

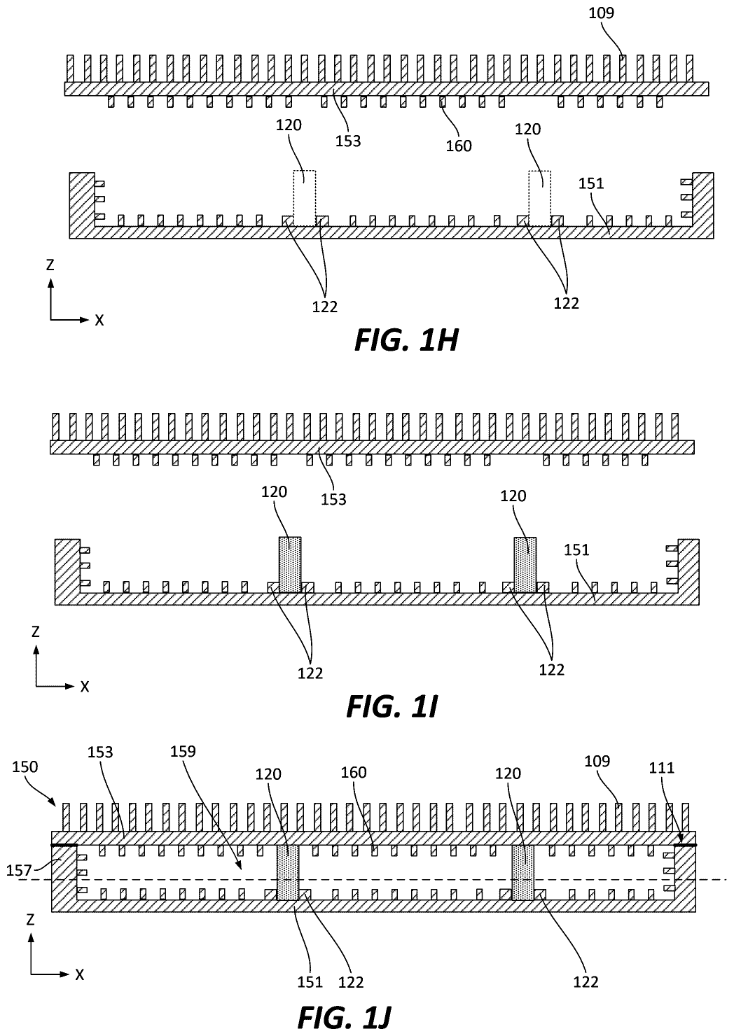

FIGS. 1A-1C are schematic cross-sectional views of different examples of a multiphase heat exchanger 100, which may be referred to as a dual-phase heat exchanger. At least some components, e.g., wicking structures 160 of these heat exchangers 100 may be fabricated using ECAM as further described below. A multiphase heat exchanger 100 may be used on a heat source 192, various examples of which are within the scope, e.g., a central processing unit (CPU), a graphical processing unit (GPU), an application-specific integrated circuit (ASIC), a field-programmable gate array (FPGA), a chipset, a power amplifier, a memory module, and a power management integrated circuit (IC). For example, a combination of a multiphase heat exchanger 100 and a heat source 192 may be referred to as a heat exchanger assembly 190.

Referring to FIG. 1A, a multiphase heat exchanger 100 comprises an evaporator base 151, a condenser base 153, a liquid-return base 155, and wicking structures 160. The evaporator base 151 comprises a heat-source interface 101 for thermal coupling to the heat source 192. The condenser base 153 is spaced away from the evaporator base 151 by a cavity 159 configured to contain a heat-transfer fluid 180. The condenser base 153 comprises an external heat-release interface 102, e.g., for thermal coupling to an external heat-transferring unit 109. The liquid-return base 155 extends between the evaporator base 151 and the condenser base 153. The wicking structures 160 are electrochemically deposited on a base surface 170 formed by at least one of (a) the evaporator base 151 forming an evaporator 152, (b) the condenser base 153 forming a condenser 154, or (c) the liquid-return base 155 forming a liquid-return portion 156. In some examples, the wicking structures 160 are only a part of the evaporator 152, only a part of the condenser 154, or only a part of the liquid-return portion 156. Alternatively, the wicking structures 160 are parts of two or all components of the multiphase heat exchanger 100.

A combination of the evaporator 152, condenser 154, and liquid-return portion 156 may be also referred to as a multiphase heat-transferring unit 150, to differentiate from other components of the multiphase heat exchanger 100. Specifically, the evaporator 152 is configured to evaporate the heat-transfer fluid 180, from a liquid phase to gas phase, upon receiving heat from heat source 192 through the heat-source interface 101. The condenser 154 is configured to condense the heat-transfer fluid 180, from the gas phase to the liquid phase, by releasing heat through the external heat-release interface 102. The liquid-return portion 156 is configured to return the heat-transfer fluid 180, in the liquid phase, from the condenser 154 to the evaporator 152.

### Evaporator Pitch Examples

Referring to FIG. 1A, the wicking structures 160 protrude into the cavity 159 away from the base surface 170. In some examples, any two adjacent ones of the wicking structures 160, attached to the evaporator base 151, are spaced apart by an average pitch selected to maintain the heat-transfer fluid 180, in the liquid phase, in contact with the at least one of the evaporator base 151 during operation of the multiphase heat exchanger 100. That is, any two adjacent wicking structures 160 are spaced to retain a liquid bridge or meniscus between them, such that capillary improves saturation as much as it reduces dry out. For example, the average pitch may be in a range of 1-1000 micrometers or, more specifically, 2-500 micrometers, 5-200 micrometers, or even 10-100 micrometers depending on the surface tension, viscosity, and boiling point of the heat-transfer fluid 180. This configuration promotes consistent wetting of the heated surface, enables nucleate boiling conditions, and enhances thermal performance by sustaining efficient fluid replenishment during phase change cycling. Also, it should be noted that such values of the average pitch are generally hard to achieve with conventional fabrication techniques.

Referring to FIG. 1A, in some examples, the evaporator 152 and the condenser 154 are laterally aligned. With reference to the gravitational vertical (during the operation of the multiphase heat exchanger 100), the evaporator 152 may be positioned below the condenser 154. This arrangement provides a short distance for the vapor of the heat-transfer fluid 180 to travel from the evaporator 152 to the condenser 154. For example, in addition to the diffusion (driven by the partial vapor pressure differential within cavity 159), the heated vapor may be carried up along the gravitational vertical by the lower density (due to heating). At the same time, the condensed heat-transfer fluid 180 may be carried from the condenser 154 back to the evaporator 152 by both capillary action (through the liquid-return portion 156) and, in some examples, by dripping from the condenser 154 to the evaporator 152 (e.g., when the condenser 154 is positioned directly above the evaporator 152).

Referring to FIG. 1B, in some examples, the evaporator 152 and the condenser 154 are laterally offset. This example allows the multiphase heat exchanger 100 to fit in tight spaces, which are complex electronic systems.

Referring to FIG. 1C, the multiphase heat-transferring unit 150 comprises one or more bridging portions 158, extending between and connected to each of the first wall and the second wall. The bridging portions 158 provide structural support to the two walls (e.g., allowing the load to be applied to the walls without bending the walls and without requiring bulky structures). Furthermore, these bridging portions 158 may be operable as liquid-return portion 156. For example, each of the one or more bridging portions 158 comprises additional wicking structures electrochemically deposited on the one or more bridging portions 158 and protruding into the cavity 159.

Referring to FIG. 1D, in some examples, the multiphase heat-transferring unit 150 comprises one or more added bridges 120, which are, unlike bridging portions 158 in FIG. 1C may be separately fabricated structures. Specifically, added bridges 120 may not be formed using ECAM but are added during the overall assembly of the multiphase heat-transferring unit 150 as further described below. Furthermore, in these examples, the condenser base 153 and the evaporator base 151 may be separate components, e.g., separately machined, and joined together at later operations. The separation of these bases provides access to the cavity 159, e.g., to install the added bridges 120 and/or form the wicking structures 160 on the interior surfaces of these bases. Specifically, ECAM may be tailored to fabricate smaller complex components, such as wicking structures 160, while the bulkier components (e.g., the evaporator base 151, the condenser base 153, and the added bridges 120) may be formed by other techniques (e.g., machined), thereby reducing the ECAM processing time and expediting the overall fabrication time.

FIGS. 1E-1J are schematic cross-sectional views of different stages during the fabrication of the multiphase heat exchanger 150 in FIG. 1D, in accordance with some examples. Specifically, FIG. 1E illustrates an evaporator base 151 and a condenser base 153 prior to forming any ECAM features (e.g., wicking structures 160) on these bases. FIG. 1E also illustrates an orientation of mating surfaces on both bases. In this example, these mating surfaces extend parallel to the main plane (the X-Y plane) of the multiphase heat-transferring unit 150, which may be defined by the evaporator base 151 and condenser base 153. FIG. 1F illustrates another example, in which the mating surfaces extend perpendicular to the main plane (the X-Y plane) of the multiphase heat-transferring unit 150. Overall, various combinations of these examples and other angles may be used for mating. Furthermore, different metal mating/attaching techniques may be used for connecting the evaporator base 151 and condenser base 153, such as brazing (e.g., using a filler metal such as silver, low-temperature copper alloys), soldering, swaging, flaring, ultrasonic welding, laser welding, and other techniques.

Furthermore, one or both of the evaporator base 151 and condenser base 153 may include side walls 157, thereby being in the form of a “C-shaped” structure. For example, FIG. 1E illustrates side walls 157 being entirely a part of the evaporator base 151, while FIG. 1G illustrates side walls 157 being entirely a part of the condenser base 153. In further examples, a first subset of side walls 157 may be a part of the evaporator base 151, while another subset of side walls 157 may be a part of the condenser base 153, such that the two subsets are then mated together to form the cavity 159 of the multiphase heat-transferring unit 150. Furthermore, the side walls 157 may be initially an independent structure from both the evaporator base 151 and condenser base 153, and later mated to each of the evaporator base 151 and condenser base 153.

Referring to FIG. 1H, the evaporator base 151 and, separately, the condenser base 153 may be subjected to ECAM processing, e.g., to form wicking structures 160 on selected surfaces of these bases. In some examples, an external heat-transferring unit 109 may also be formed during this ECAM operation, e.g., on the condenser base 153. Alternatively, the external heat-transferring unit 109 may be formed as a standalone unit that is later attached to the condenser base 153. Furthermore, mating structures 122 may be formed during this ECAM operation. These mating structures 122 may be specifically configured to engage with the added bridges 120. Various examples of added bridges 120 and this engagement are described below.

Referring to FIG. 1I, the added bridges 120 are inserted into and engaged with the mating structures 122. While FIG. 1I illustrates the added bridges 120 are initially engaged with the evaporator base 151, in other examples, the added bridges 120 may be first engaged with the condenser base 153 or both the evaporator base 151 and the condenser base 153. Furthermore, while FIG. 1I illustrates the added bridges 120 extending between the evaporator base 151 and condenser base 153 (e.g. in the direction perpendicular to the main plane of the multiphase heat-transferring unit 150), in other examples, added bridges 120 may be extended between and engaged with the side walls 157 (e.g., in the direction parallel to the main plane of the multiphase heat-transferring unit 150). In this side-wall engagement example, one or more side walls 157 may be later attached. Furthermore, it should be noted that mating structures 122 may be used to support only one end of each added bridge 120 or both ends of each added bridge 120.

Finally, FIG. 1J illustrates the manufacturing stage after mating the evaporator base 151 and condenser base 153, at which point the cavity 159 is formed and may be filled with a heat-transfer fluid 180.

Overall, the added bridges 120 provide support to the evaporator base 151 and condenser base 153 relative to each other, thereby allowing to pressurize/de-pressurize the cavity 159 (relative to the ambient environment). The added bridges 120 may also help to align the evaporator base 151 and condenser base 153 relative to each other during fabrication of the multiphase heat-transferring unit 150 (e.g., before and/or during mating these bases). As noted above, mating structures 122 provide support to added bridges 120 and may engage using one or more techniques selected from the group consisting of tight fit (e.g., tapered cylinders), threaded coupling, tapered cylinders, soldering, and welding.

The added bridges 120 may be shaped like, e.g., cylinders, rectangular prisms, hexagonal prisms, etc. The added bridges 120 may be elongated structures (narrow and long support structures, such as having an aspect ratio of at least 5, at least 10, or even at least 20). In some examples, the material of the added bridges 120 is the same as the evaporator base 151 and condenser base 153 (e.g., all made from copper). However, different materials may be used for the added bridges 120, in some examples.

In some examples, added bridges 120 may divide the cavity 159 into multiple sub-cavities. Each sub-cavity may have different characteristics, such as physical designs and/or refrigerant chemicals. Such configurations may allow for multi-domain heat transfer tailored to different zones of interest. For example, different zones may require different heat flux densities based on the heat output of the heat source 192 (e.g., the heat source 192 may have hot spots associated with localized heat generation). Sub-cavities may be specifically configured to accommodate different heat flux density requirements across the interface between the heat source 192 and the multiphase heat-transferring unit 150.

In some examples (not shown), thermal interface 194 may be omitted, for example, when the base and/or wicking structures 160 are electrochemically deposited onto the thermal source 192, in which case seed layers of conductive material may be employed.

### Condenser Capillary Aspects

In some examples, the wicking structures 160, attached to the condenser base 153, are configured to enhance capillary pumping of the heat-transfer fluid 180, in liquid phase, away from the condenser base 153. Specifically, wicking structures 160 may have geometries tailored to enhance capillary flow while maintaining sufficient vapor access to the base surface 170. For example, the wicking structures 160 may include micro-grooved ridges, posts, or reentrant cavity arrays having cross-sectional widths of 10-1000 micrometers or, more specifically, 50-500 micrometers. The average pitch between adjacent structures may be in a range of 10-1000 micrometers or, more specifically, 50-500 micrometers, depending on the properties of the heat-transfer fluid 180 and the orientation of the multiphase heat exchanger 100. The wicking structures 160 may protrude into the cavity 159 to a height of approximately 50-3,000 micrometers or, more specifically, 200-2,000 micrometers. It should be noted that electrochemical deposition or, more specifically, ECAM, helps to ensure conformal adhesion and precise geometric control.

### Wicking Structures in Liquid-Return Portions

In some examples, the wicking structures 160, attached to the liquid-return base 155 and forming a liquid-return portion 156, vary in size or pitch along a direction from the condenser 154 to the evaporator 152 to compensate for changes in the gravitational and/or capillary head. For example, the evaporator 152 may be below or above condenser 154 (along the gravitational vertical, e.g., as shown in FIG. 1A). This orientation helps to utilize the gravitation forces and changes in density as the heat-transfer fluid 180 evaporates/condenses to move the heat-transfer fluid 180 within each of the evaporator 152 and condenser 154 and between the evaporator 152 and condenser 154. For example, the gas/vapor phase of the heat-transfer fluid 180 may simply diffuse through the cavity 159, while the liquid phase may require the liquid-return portion 156 to move from the condenser 154 back to the evaporator 152.

The geometry of the wicking structures 160, attached to the liquid-return base 155 and forming the liquid-return portion 156, may vary along the return path, e.g., by changing pitch, cross-sectional area, or height. Such variation helps maintain a stable liquid supply to the evaporator 152 and supports reliable operation across a range of device orientations and thermal loads.

### Additional Examples of Wicking Structures

In some examples, the wicking structures 160 are electrochemically deposited on both the evaporator base 151 and the liquid-return base 155. In these examples, the pitch of the wicking structures 160 electrochemically deposited on the evaporator base 151 is greater than the pitch of the wicking structures 160 electrochemically deposited on the liquid-return base 155. Specifically, the wicking structures 160 electrochemically deposited on the evaporator base 151 are configured to maximize the heat transfer, while the wicking structures 160 electrochemically deposited on the liquid-return base 155. The larger pitch allows more liquid to get in and as the liquid evaporates the pitch is reduced while also increasing the heat transfer rate to the remaining fluid]

In some examples, at least in the evaporator 152, the wicking structures 160 have a nucleation point density of at least 10/mm², at least 100/mm², or even at least 100/mm² based on the surface area of the base surface 170. For purposes of this disclosure, a nucleation point is defined as an edge or a corner having a curvature radius of less than 10 micrometers or even less than 1 micrometer. The high density of these nucleation points promotes efficient boiling in evaporator 152.

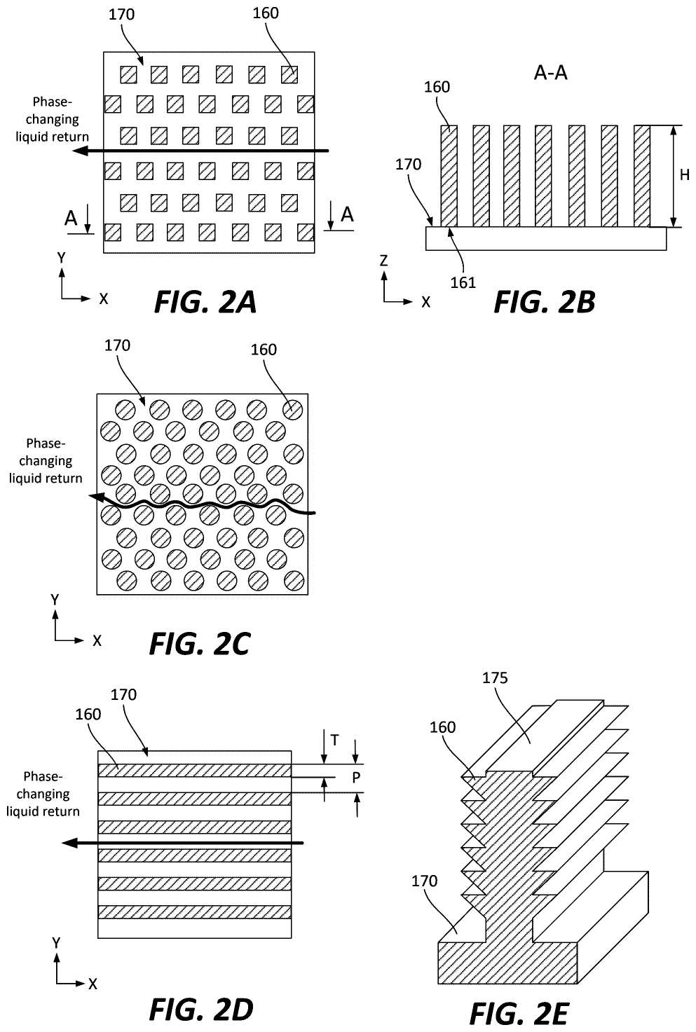

Referring to FIGS. 2A-2B, in some examples, each of the wicking structures 160 is a 1-dimensional column comprising a base 161, which is growth rooted to the base surface 170 by electrochemical deposition. A 1-dimensional (1D) column may be defined as a structure in which a dimension along one axis (e.g., perpendicular to the base surface 170, which may be referred to as a “height” (H)) is at least 3 times greater than the dimensions along any of the two-remaining axis.

The columns may have different cross-sectional profiles within a plane parallel to the base surface 170, e.g., square/rectangular (as shown in FIGS. 2A and 2D), oval/circular (as shown in FIG. 2C), irregular shape, and the like. This shape may be determined by the heat transfer and/or capillary action characteristics. In some examples, the cross-sectional profiles, dimensions, spacing, and/or material composition of all wicking structures 160 in a set portion of the multiphase heat-transferring unit 150 are the same. Alternatively, at least one of the cross-sectional profiles, dimensions, spacing, and/or material composition may be different for different subsets of the wicking structures 160 at the same location within the multiphase heat-transferring unit 150.

Referring to FIG. 2A, in some examples, the wicking structures 160 are arranged into a set of rows. The wicking structures 160 in two adjacent rows in this set of rows are offset relative to each other forming a straight channel for a heat-transfer fluid 180. Alternatively, referring to FIG. 2B, the wicking structures 160 are offset relative to each other such that a heat-transfer fluid 180 needs to continuously reroute through the gaps between these wicking structures 160.

Referring to FIG. 2D, in some examples, each of the wicking structures 160 is a 2-dimensional (2D) wall comprising a base 161, growth rooted to the base surface 170 by electrochemical deposition. As such, two adjacent “wall” wicking structures 160 form a continuous gap for the heat-transfer fluid 180 to travel. These gaps may be straight (e.g., as in FIG. 2D) or wavy (e.g., sinusoid, square waves, etc.).

The wicking structures 160 may be in the form of straight prisms/columns as they extend from the base surface 170 (e.g., as shown in FIG. 2B). In such straight prisms/columns, the cross-sectional shape and size remain the same for the entire height of the wicking structures 160. Alternatively, the wicking structures 160 in the form of prisms, cones, pyramids, cylinders, spheres, spherical sections, and general polyhedrons. Furthermore, wicking structures 160 may be lattice and TPMS structures, uniform and composite structures, composite gyroid, body-centered-cubic (BCC), composite body-centered-cubic (BCC), meshes, and the like. The shapes are enabled by ECAM fabrication techniques, which are further described below.

Overall, the wicking structures 160 formed by ECAM may be referred to as ECAM wicking structures while the space between these wicking structures 160 may be referred to as wicking microchannels or ECAM wicking microchannels. As noted above, ECAM allows for control of various structural (e.g., geometric, compositional) characteristics of the wicking structures 160 while these wicking structures 160 are formed using ECAM. For example, channel gap channels may be controlled to ensure the flow of the heat-transfer fluid within the multiphase heat-transferring unit 150. The geometric features (e.g., edges, pores) of the wicking structures 160 may be specifically controlled based on specific requirements of the condenser 154 and evaporator 152. For example, fluid and energy transfer is completely passive within the multiphase heat-transferring unit 150 when heat is applied to the evaporator base 151. For example, the wicking structures 160, attached to the evaporator base 151 (evaporator wicks), utilize lower liquid pressure while the wicking structures 160 attached to the condenser base 153 (condenser wicks) are at higher liquid pressure, which forms the pumping mechanism. The capillary pressure differential is presented by the following equation, wherein Pc is the capillary pressure, σ is the surface tension of the liquid, θ is the contact angle between the liquid and the solid surface, and r is the radius of curvature of the interface.

$$Δ {P}_{c} = \frac{2 σ}{{r}_{eff}} \cdot cos θ$$

Therefore, increasing pore dimension increases permeability but decreases capillary pressure. In general, a K/R_{eff} parameter in the following equation can be used to compare hydraulic performance. This parameter combines permeability (K) and effective capillary resistance (R_{eff}) into a single figure of merit.

$${Q}_{max , cap} ≅ 2 ( \frac{{ρ}_{l} σ {h}_{fg}}{{μ}_{l}} ) ( \frac{{A}_{w}}{{L}_{eff}} ) ( \frac{K}{{R}_{eff}} )$$

where Q_{max,cap} denotes the maximum capillary heat transport limit, ρi—density of the liquid, σ—surface tension of the liquid, h_{fg}—latent heat of vaporization, μₗ—dynamic viscosity of the liquid, A_{w}—cross-sectional area of the wick, L_{eff}—effective length.

FIG. 2E is another example of wicking structures 160, in the form of triangular protrusions that form grooves, other than 90° overhangs. For example, walls with triangular cross-sections may be easily fabricated using ECAM. In other examples, the groove shapes may be rectangular, trapezoidal, and the like.

### Tortuous Path-Forming Wicking Structures

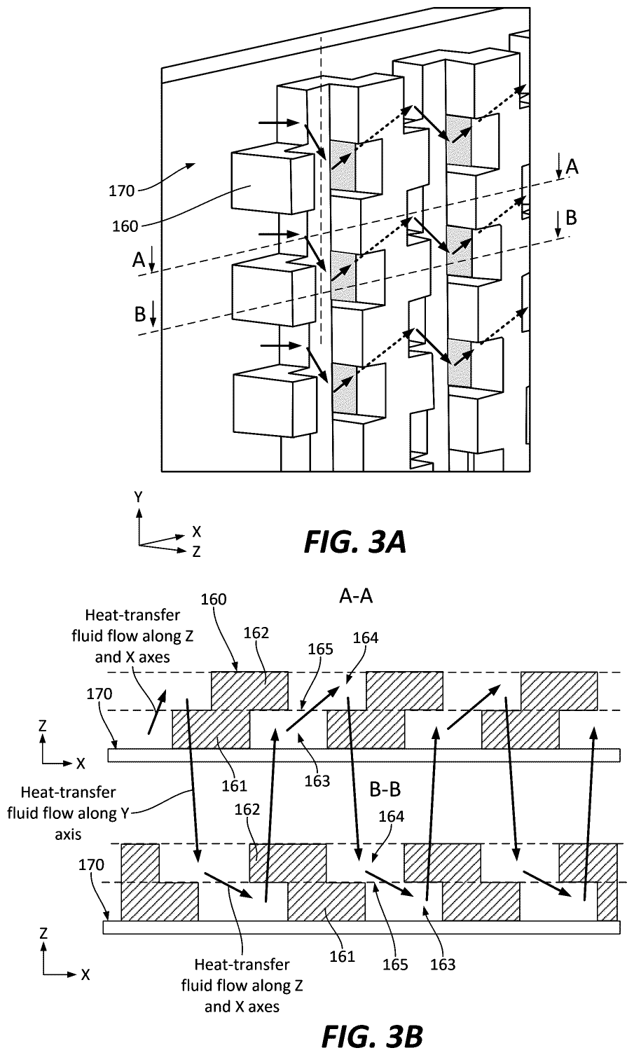

FIG. 3A is a schematic perspective view of wicking structures 160 forming tortuous paths for heat-transfer fluid 180, proximate to the base surface 170, in accordance with some examples. FIG. 3B illustrates two cross-sectional views of the wicking structures 160 in FIG. 3A to illustrate some aspects of the tortuous paths. Specifically, the wicking structures 160 are configured to direct the heat-transfer fluid 180 in all three directions as the heat-transfer fluid 180 is proximate to the base surface 170.

Referring to FIG. 3B, each of the wicking structures 160 comprises a base 161 and an overhang 162. Base 161 is electrochemically deposited on the base surface 170, positioned between the overhang 162 and the base surface 170, and supports the overhang 162 relative to the base surface 170. The overhang 162 protrudes beyond a footprint of the base 161 thereby forming a lower cavity 163 proximate to the base surface 170. The overhang 162 of two adjacent ones of the wicking structures 160 are spaced forming an upper cavity 164, fluidically coupled with the lower cavity 163 by an opening 165.

Overall, arrangements of wicking structures 160 may be specifically tailored to promote multidirectional flow and form a network of tortuous paths that facilitate capillary-driven and non-capillary flow along the X, Y, and Z directions. When used in an evaporator 152, these paths enable the liquid phase of the heat-transfer fluid 180 to remain in contact with the base surface 170 during operation, even under conditions of localized vapor generation or increased heat flux. The base 161 and overhang 162 may be formed using ECAM, which allows for high-resolution control over the height, pitch, and overhang dimensions of the wicking structures 160. The average pitch between adjacent structures 160 may be selected to maintain capillary continuity while accommodating vapor escape. In some examples, the overhangs 162 extend laterally beyond the footprint of the base 161 by at least 20-50% of the base width, thereby enlarging the lower cavity 163 and increasing fluid retention capacity. The structural arrangement of the wicking features may be repeated or graded across the evaporator base 151, with variations in geometry tuned to accommodate local heat flux distributions or expected vapor loadings.

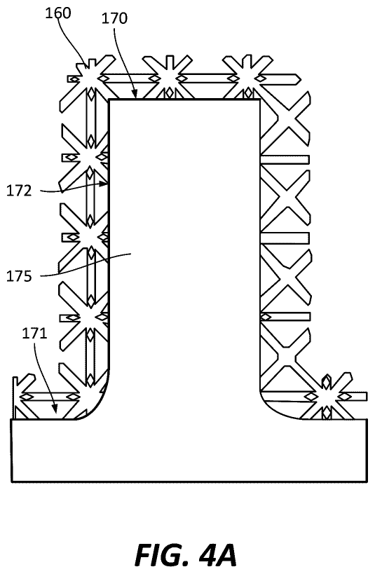

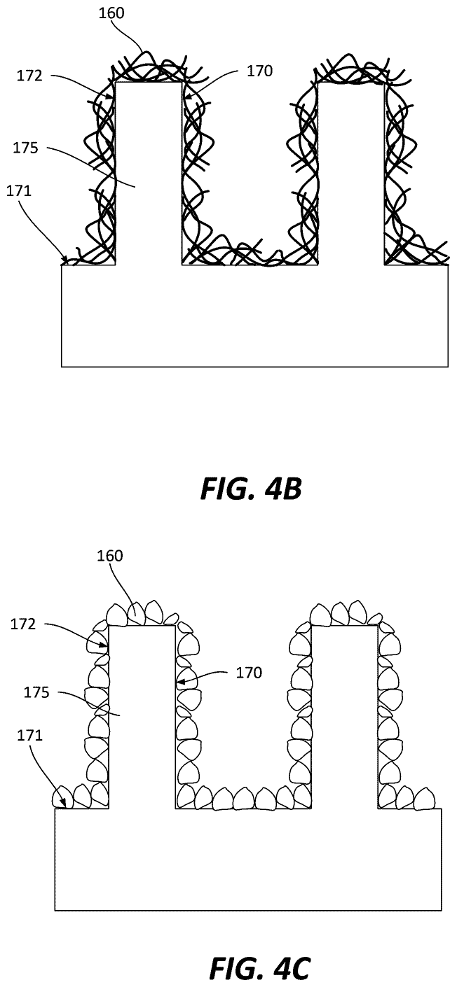

FIGS. 4A-4C are schematic side views of different examples of wicking structures 160 electrochemically formed on protrusions 175. In general, wicking structures 160 may be electrochemically deposited on a base surface 170, which may be a part of the evaporator base 151, the condenser base 153, and/or the liquid-return base 155. In other words, a base surface 170 is a part of one or more base structures, which may be parts of the evaporator base 151, the condenser base 153, and/or the liquid-return base 155.

The base surface 170 may be substantially planar/flat. Alternatively, the base surface 170 may be non-planar, e.g., have a first surface portion 171 and a second surface portion 172 that is not in the same plane as the first surface portion 171. For example, one or both first surface portion 171 and second surface portion 172 may be non-planar and/or may be positioned at a certain angle (>) 0° relative to each other. FIGS. 4A-4C illustrates an example in which the first surface portion 171 is planar, while the second surface portion 172 is shaped and defines protrusions 175, extending away from the first surface portion 171. Such protrusions 175 may be used to increase the area of the base surface 170, e.g., for more contact with the heat-transfer fluid 180 and accommodate more wicking structures 160.

In some examples, the base structures (and any of its components, e.g., protrusions 175) may be formed from copper, and other suitable materials. Wicking structures 160 are used to conduct the heat away from the base surface 170 and also to assist the fluid (e.g., as gas and liquid) mobility along the base surface 170 as well as to/from the base surface 170, in addition to the phase change (gas-liquid), e.g., by providing nucleation points.

For example, in an evaporator 152, it is highly desirable to keep the gas phase of the heat-transfer fluid 180 away from the base surface 170. As such, the wicking structures 160 are specifically configured to pump the liquid phase of the heat-transfer fluid 180 to the base surface 170 as well as promote its boiling. Such wicking structures 160 may be used for two-phase cooling, especially in vapor chamber or wicking applications where capillary action is beneficial. Specifically, wicking structures 160 (shown in FIGS. 4A-4C) provide many nucleation sites and paths for bubbles to escape. Specifically, bubbles operate as thermal insulators, and when the bubbles get trapped, the heat transfer rate is reduced, which is not desirable. FIG. 4B illustrates another example of wicking structures 160 electrochemically deposited on protrusions 175, i.e., wicking structures 160 as interwoven structures.

Other examples of wicking structures 160 include a composite gyroid, which provides a high-surface-area-to-volume ratio and may be referred to as a triply periodic minimal surface (TPMS) structure. Such TPMS structures are mathematically defined surfaces that repeat periodically in three dimensions and have zero mean curvature at every point. These structures provide excellent mechanical strength, low density, and high surface-area-to-volume ratio. Some notable characteristics include a mean curvature that is zero, meaning the surface is balanced in terms of tension. The structure repeats in three-dimensional space, forming a continuous and interconnected network. A high strength-to-weight ratio and a high-surface-area feature are useful for heat exchanger applications. Some examples of TPMS structures include but are not limited to, gyroid (e.g., a highly interconnected and curved structure with no straight lines), Schwarz (a primitive and diamond-like TPMS surfaces), and lidinoid (e.g., a complex variation used in advanced material designs). TPMS structures may be specifically configured for the fluid flow dynamics, e.g., low-pressure drop (due to the lack of sharp edges) makes them ideal for compact cooling systems. The interconnected openings within a gyroid structure allow for better convective cooling. However, TPMS structures can not be produced by conventional methods (e.g., skiving), while ECAM is capable of producing the TPMS structures for heat-exchanging applications (e.g., EV battery cooling, microprocessors, and heat exchangers)

In some examples, functional grading is used for different parts of a multi-phase heat exchanger (e.g., a condenser region, evaporator region, and adiabatic region). For example, the lattice and/or structure density varies among wicking structures 160 (such as from denser to more porous).

In some examples, wicking structures 160 are in the form of body-centered-cubic (BCC). A specific example of such wicking structures 160 is a composite body-centered-cubic (BCC). These types of wicking structures 160 have lattice structures that are optimized for “K/r”, with “K” being permeability, and “r” being effective pore radius. The “K/r” is a useful variable or parameter to understand the balance between the capillary pressure and permeability, i.e., how easily the fluid flows through something. These examples of wicking structures 160 are suitable for wicking structures and 2-phase cooling. FIG. 4C illustrates yet another example of wicking structures 160 electrochemically deposited on protrusions 175, i.e., wicking structures 160 as particles.

In general, wicking structures 160 may be either 1D structures, 2D structures, or 3D structures. The dimensionality of wicking structures 160 may be defined by the number of orthogonal directions (as related to each structure) in which the structure substantially extends. In some examples, wicking structures 160 may be in the form of one-dimensional (1D) structures, e.g., structures in which the largest dimension in one direction is substantially greater (e.g., at least 5 times greater or at least 10 times greater) than the corresponding dimensions in the other two orthogonal directions. Such 1D structures may include wires, columns, and posts. It should be noted that such 1D structures do not need to be straight along this principal (largest dimension). The cross-sectional profile of these 1D structures may be round, oval, rectangular, polygonal (e.g., hexagonal), or irregular. In other examples, wicking structures 160 may be in the form of two-dimensional (2D) structures, e.g., structures in which the largest dimensions in two orthogonal directions are substantially greater (e.g., at least 5 times greater or at least 10 times greater) than the third orthogonal direction. Such 2D structures may include porous fins, sheets, and films, designed to increase the surface contact with the heat-transfer fluid 180. In further examples, wicking structures 160 may be in the form of three-dimensional (3D) structures, e.g., structures in which the largest dimensions in all three orthogonal directions are of comparable magnitude (e.g., none of the dimensions are substantially greater than the others, such as all within a factor of 5 or within a factor of 10). Such 3D structures may include interconnected particles, meshes, and lattices.

Overall, the performance of wicking structures 160 within a multiphase heat exchanger is governed by a variety of geometric, spatial, and material characteristics. These characteristics affect key performance metrics such as capillary-driven liquid transport, phase-change efficiency, and thermal transfer. Electrochemical additive manufacturing (ECAM) uniquely enables precise control over these attributes with micron-scale resolution, offering design capabilities that surpass traditional methods such as sintering or foam-metal bonding. For example, pore size and pore size distribution may influence capillary pressure and permeability of the wicking structures 160 by both liquid and gas phases of the heat-transfer fluid 180. Smaller pores generate higher capillary suction, which is advantageous for sustaining liquid flow toward evaporation zones, especially against gravity. In some examples, the pore size of wicking structures 160 are 10-200 micrometers and 20-80 micrometers. It should be noted that the pore size depends on the material and the surface finish of the wicking structures 160 and the composition (surface tension) of the heat-transfer fluid 180.

Some examples of heat-transfer fluids 180 include but are not limited to a hydrofluorocarbon refrigerant (e.g., 1,1,2-tetrafluoroethane (R-134a), 1,1,2,2,3-pentafluoropropane (R-245ca), R-410A, R-404A), a hydrocarbon refrigerant (e.g., propane (R-290), isobutane (R-600a), pentane (R-601), a chlorofluorocarbon refrigerant (e.g., dichlorodifluoromethane (R-12)), ammonia (R-717), water, alcohols, ketones, oils, alkali metals. Specific examples include 3M's Fluorinert FC-72, Novec 7100, Novec 649, and National R-1233zd. Some of the above-referenced fluids are dielectric and may be used in direct contact with electronic components (e.g., for two-phase immersion cooling (2PIC)) where wicking structures 160 are arranged in a “direct to die”/“direct to heat source” configuration. In general, the selection of heat-transfer fluid 180 depends on the temperatures of the heat source and heat recipient (e.g., environment, another fluid), the internal pressure of the multiphase heat-transferring unit 150, and other characteristics.

Another characteristic is the porosity (void fraction) of the wicking structures 160. High porosity improves fluid retention and permeability but may reduce thermal conduction through the wick. In some examples, the porosity is 20-90% or, more specifically, 30-80%, such as 40-70%. It should be noted that ECAM enables the fabrication of graded porosity regions, for example increasing porosity near the inlet to facilitate fast liquid priming while using denser structures near the heat source to ensure structural contact and thermal conduction, i.e. locally varying the effective thermal conductivity by using higher volume fraction of the filled (occupied) space vs. free space.

Referring to FIGS. 2A-2E and FIG. 4A, the geometry of wicking structures 160 and the connectivity of the wicking structures 160 can be specially configured to the operating conditions of the multiphase heat exchanger 100 and can be controlled using ECAM techniques. Additional characteristics of the wicking structures 160 include thickness and spatial placement, with ECAM enabling localized control. Furthermore, surface roughness, texture, and wettability of wicking structures 160 may be controlled using ECAM. For example, micropatterned surfaces improve wetting dynamics and nucleation site density, leading to enhanced heat transfer. In some examples, wicking structures 160 comprise vapor escape paths or separate fluid domains (e.g., one for the gas phase and one for the liquid phase) to reduce phase interference and enhance heat transfer.

### External Heat-Transferring Units

Referring to FIGS. 1A-1C, in some examples, a multiphase heat exchanger 100 comprises an external heat-transferring unit 109, thermally coupled to the multiphase heat-transferring unit 150 or, more specifically, to the condenser 154 or even to the condenser base 153. For example, the external heat-transferring unit 109 may be electrochemically deposited on the condenser base 153. In more specific examples, the external heat-transferring unit 109 and the condenser base 153 are formed from different materials. The external heat-transferring unit 109 may comprise heat-transferring structures extending away from the condenser base 153 in a direction opposite of the evaporator base 151.

The external heat-transferring unit 109 may be used for dissipating heat away (e.g., air-cooled, liquid-cooled, etc.). It should be noted that any heat-transfer fluids that come in direct contact with the external heat-transferring unit 109 are different from a heat-transfer fluid 180 contained within the multiphase heat-transferring unit 150. The thermal coupling of the external heat-transferring unit 109 and multiphase heat-transferring unit 150 may be provided by direct contact/interface, material continuity (e.g., the external heat-transferring unit 109 and multiphase heat-transferring unit 150 being monolithic with each other), attaching using heat-transferring structures (e.g., a thermal interface materials (TIM)), and the like. In some examples, the external heat-transferring unit 109 is formed directly on the multiphase heat-transferring unit 150, e.g., using ECAM.

### Examples of Fabricating Multiphase Heat Exchangers

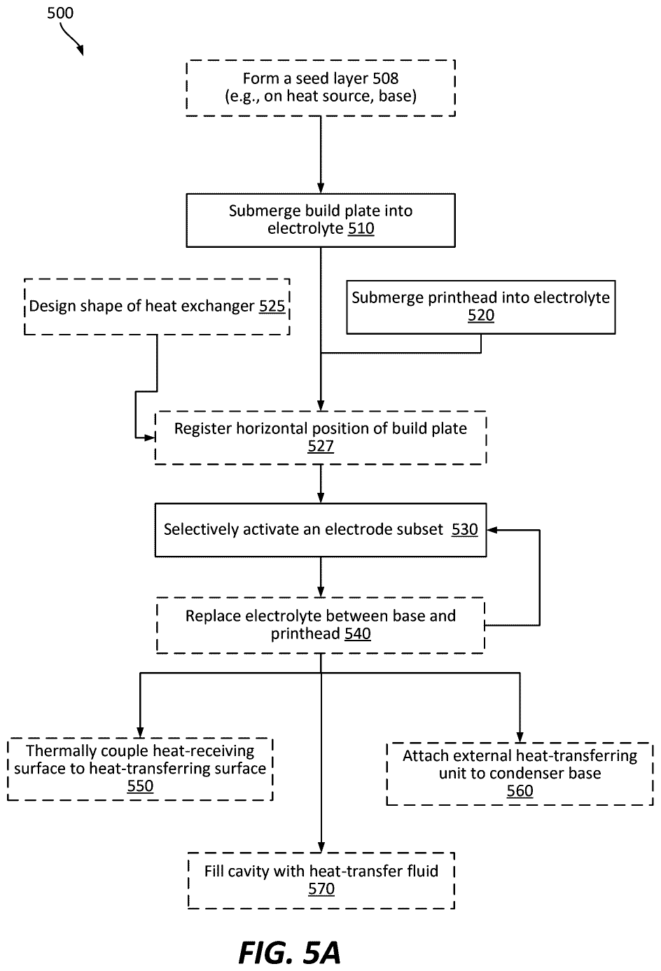

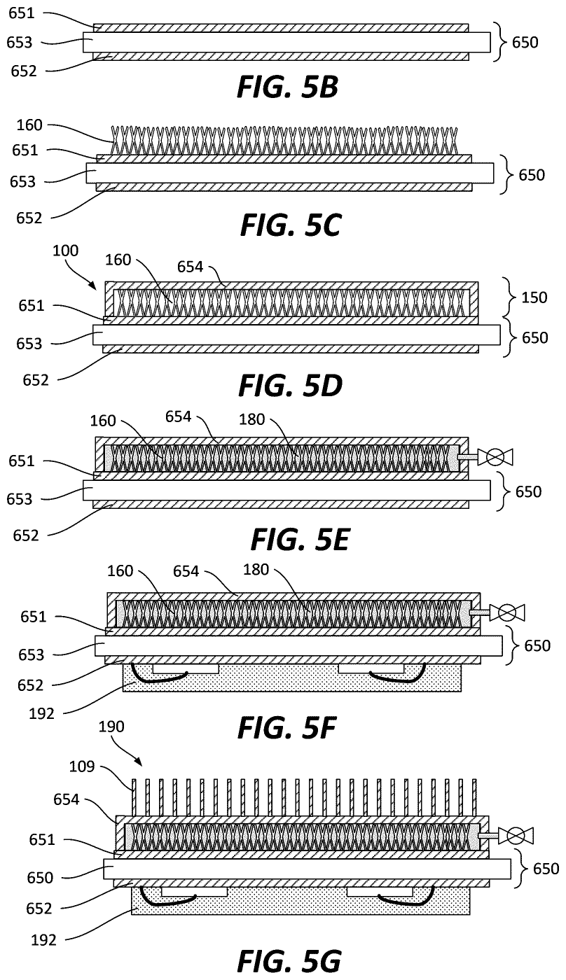

FIG. 5A is a process flowchart corresponding to method 500 for fabricating a multiphase heat exchanger 100 using electrochemical additive manufacturing (ECAM), in accordance with some examples. Various aspects of this method 500 enable precise, localized electrochemical deposition, providing enhanced control over the geometry and material composition of the multiphase heat exchanger 100 or, more specifically, of the wicking structures 160, allowing for the fabrication of complex (e.g., nonlinear) geometries that are not possible with conventional methods such as skiving, sintering, or foam-metal bonding.

Referring to FIG. 5A, in some examples, method 500 comprises (block 510) submerging a build plate 650 comprising a deposition surface into an electrolyte 680. Various aspects of the electrolyte 680 (e.g., containing various metal ions used for fabricating wicking structures 160) are described below. The build plate 650 comprises one or more components selected from the group consisting of an evaporator base 151, a condenser base 153, and a liquid-return base 155. In some examples, the heat source 192 is also a part of the build plate 650 submerged into the electrolyte. For example, the evaporator base 151 may be a component of the heat source 192 (e.g., in a “direct to die” example). As noted above, the heat source 192 may be selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC).

Overall, the submersion of the build plate 650 into the electrolyte 680 creates the necessary environment for electrochemical deposition, e.g., providing ion exchange and material deposition while enabling precise control over the material composition at different locations on the deposition surface.

In some examples, prior to (block 510) submerging the build plate 650 into the electrolyte 680, method 500 comprises (block 508) forming a seed layer on the build plate 650 (e.g., a heat source 192 or, more specifically, a die). For example, the build plate 650 may initially have a surface that is not conductive, which would not allow electrochemical deposition. A seed layer may be deposited, e.g., using sputtering/physical vapor deposition (PVD), electroplating (electroless), and thermal/direct bonding. The seed layer is formed from a conductive material (e.g., copper) and, in turn, forms a deposition surface. The conductive seed layer allows the system to electrochemically form the wicking structures 160 on otherwise a non-conductive base (e.g., a dielectric material) the heat source 192. However, a conductive seed layer is optional (e.g., when at least the deposition surface of the build plate 650 is sufficiently conductive to initiate the electrochemical deposition). The thickness of the conductive seed layer may be between about 50-150 micrometers or, more specifically, 75-125 micrometers.

Referring to FIG. 5A, in some examples, method 500 comprises (block 520) submerging a printhead 610 into the electrolyte 680 and proximate to the deposition surface. As further described below, the printhead 610 comprises a set of pixelated electrodes 620 and electrode-array drivers 616. Specifically, these pixelated electrodes 620 allow for highly localized and selective material deposition. Unlike conventional electroplating techniques that apply a uniform current across an entire surface, the use of pixelated electrodes 620 enables spatial control over deposition, leading to complex geometries and fine structural features necessary for high-performance heat exchangers. This capability allows the formation of nonlinear geometries, specially configured fluidic pathways, and material composition that would be unattainable with traditional fabrication methods such as skiving.

Referring to FIG. 5A, in some examples, method 500 further comprises registering (block 527) the horizontal position of the build plate 650 relative to the printhead 610 using a mapping process based on the shape of the build plate 650. This registering operation (block 527) is performed after (block 510) submerging the build plate 650 and (block 520) submerging the printhead 610 and before (block 530) selectively activating the electrode subset.

Referring to FIG. 5A, in some examples, method 500 comprises (block 530) selectively activating an electrode subset from the set of pixelated electrodes 620 using the electrode-array drivers 616 thereby generating an ionic flow through the electrolyte 680 between the electrode subset and a portion of the deposition surface aligned with the electrode subset thereby electrochemically depositing wicking structures 160. As noted above, the ability to control individual electrodes enables precision in material deposition thereby allowing complex geometries of the wicking structures 160, e.g., optimized heat transfer.

The operation represented by (block 530), i.e., selectively activating an electrode subset from the set of pixelated electrodes 620, may be repeated multiple times with different electrode subsets thereby changing the geometry/cross-section of the wicking structures 160 as it extends away from the build plate 650. ECAM is an additive manufacturing process, which deposits a new layer in each deposition cycle. The footprint of each layer depends on the subset of pixelated electrodes 620 activated during this cycle.

In some examples, prior to (block 530) selectively activating the electrode subset, method 500 comprises (block 525) designing the shape of the multiphase heat exchanger 100 and developing a set of deposition maps corresponding to the shape of the multiphase heat exchanger 100 or, more specifically, the shape of wicking structures 160. For example, each deposition map represents one ECAM deposition cycle that forms a shaped deposit. Specifically, the deposit is a layer with a shape determined by the location of the activated electrode subset (with the thickness of the layer determined by the duration of the deposition cycle). As such, the shape of which layer is controlled by the corresponding deposition map, while the entire share of the multiphase heat exchanger 100 or, more specifically, the shape of the wicking structures 160 is determined by the set of deposition maps. During the selectively activating operation (block 530), the electrode subset is activated based on a deposition map in the set of deposition maps.

In some examples, method 500 comprises (block 540) replacing the electrolyte 680 between the printhead 610 and build plate 650 or, more specifically, between the printhead 610 and a partially formed wicking structure 160. The electrolyte 680 may be replaced with a fresh electrolyte having the same composition (e.g., to remove gas bubbles, and replenish metal ions) or with an electrolyte having a different composition (e.g., having different metal ions). Using the electrolyte with a different composition allows varying the composition of the wicking structures 160 (at least along the direction orthogonal to the deposition surface).

In some examples, method 500 comprises (block 550) thermally coupling the evaporator base 151 to the heat-transferring surface 193 of the heat source 192. For example, this thermal coupling operation may comprise positioning a thermal interface 194 between the evaporator base 151 and the heat-transferring surface 193 (e.g., as shown in FIG. 1A). Furthermore, the thermal coupling operation may comprise mechanically attaching the evaporator base 151 to the heat source 192. It should be noted that ECAM may be performed on a heat source 192 (e.g., depositing wicking structures 160 directly on the heat-transferring surface 193). The heat source 192 may be sensitive to the electrolyte environment and, therefore, isolated from the electrolyte 680 during ECAM processing.

In some examples, method 500 further comprises (block 560) attaching an external heat-transferring unit 109 to a condenser base 153. For example, this operation may involve ECAM techniques, e.g., (a) submerging the condenser base 153 into the electrolyte 680, and (b) selectively activating the electrode subset from the set of pixelated electrodes 620 using the electrode-array drivers 616 thereby electrochemically depositing the external heat-transferring unit 109 comprising heat-transferring structures extending away from the condenser base 153 in a direction opposite of the evaporator base 151.

In some examples, method 500 further comprises (block 570) filing the cavity 159 with the heat-transfer fluid 180 selected from a group consisting of a hydrofluorocarbon refrigerant, a hydrocarbon refrigerant, a chlorofluorocarbon refrigerant, an ammonia refrigerant, and a carbon dioxide refrigerant.

FIGS. 5B-5G are schematic illustrations of different stages of fabricating a multiphase heat exchanger 100 comprising a multiphase heat-transferring unit 150, in accordance with some examples. The multiphase heat-transferring unit 150 may be also referred to as a vapor chamber. In the illustrated examples, the multiphase heat-transferring unit 150 is coupled to a heat source 192 (e.g., a power module). Specifically, FIG. 5B illustrates an example of a build plate 650, which comprises a dielectric layer 653 positioned between two metal layers, i.e., a first metal layer 651 and a second metal layer 652. The dielectric layer 653 may be formed, e.g., from silicon nitride (SiN) and aluminum nitride (AlN). In specific examples, the first metal layer 651 and second metal layer 652 may be referred to as direct bonded copper (DBC) layers. In some examples, the DBC layers on one or both sides of the dielectric layer 653 may be replaced by a sputtered metallization layer or the like.

FIG. 5C illustrates wicking structures 160 electrochemically deposited on the first metal layer 651 (e.g., using ECAM techniques described herein). FIG. 5D illustrates cover 654 enclosing the wicking structures 160 and forming a vapor chamber. For example, cover 654 may be formed from a metal (e.g., copper) and attached (e.g., braised) to the first metal layer 651 (e.g., along the perimeter surrounding the wicking structures 160). At this point, the multiphase heat-transferring unit 150 is formed. It should be noted that in this example, the cover 654 also functions as a condenser base 153 and a liquid-return base 155 (together with the wicking structures 160). In some examples, the cover 654 may be fabricated using ECAM.

FIG. 5E illustrates the vapor chamber filled with the heat-transfer fluid 180, various examples of which are described below. FIG. 5F illustrates a heat source 192 attached to the second metal layer 652, e.g., using TIM. Finally, FIG. 5G illustrates an external heat-transferring unit 109 (e.g., in the form of cooling fins) formed over cover 654, e.g., using ECAM.

### ECAM System Examples

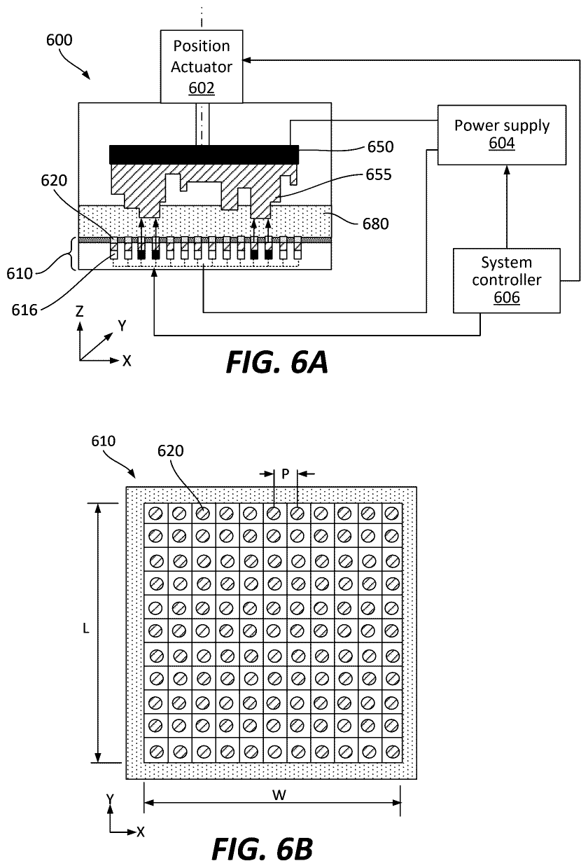

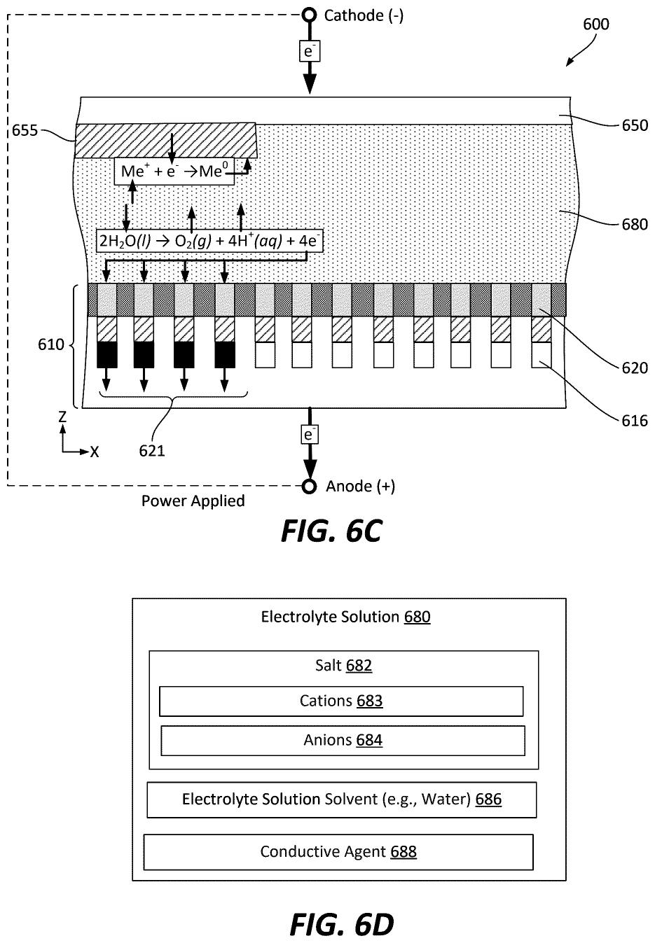

FIG. 6A is a schematic illustration of an ECAM system 600 used for depositing or, more specifically, electroplating material (e.g., copper deposit), in accordance with some examples. An ECAM system 600 may comprise a position actuator 602, a system controller 606, a deposition power supply 604, a printhead 610, and a build plate 650. In some examples, a build plate 650 is connected to the deposition power supply 604 and controllably supported relative to the ECAM printhead 610 (e.g., by position actuator 602).

An ECAM printhead 610 or simply a printhead 610 comprises a set of pixelated electrodes 620 and electrode-array drivers 616. Each of the electrode-array drivers 616 controls the current flow through a corresponding electrode in the set of pixelated electrodes 620 as well as the corresponding portion of the electrolyte 680 thereby causing the deposition on the corresponding surface of the material (e.g., copper deposit) on build plate 650.

A position actuator 602 can be mechanically coupled to the build plate 650 and used to change the positional relationship of the printhead 610 and build plate 650 (e.g., changing the gap between the printhead 610 and build plate 650 or, more specifically, the gap between the set of pixelated electrodes 620 and build plate 650, linearly moving and/or rotating one or both printhead 610 and build plate 650 within a plane parallel to the set of pixelated electrodes 620). While FIG. 6A illustrates the position actuator 602 coupled to the build plate 650, the position actuator may be coupled to the printhead 610 and/or the build plate 650. Other examples are also within the scope.

A system controller 606 is used for controlling the operations of various components. For example, FIG. 6A illustrates the system controller 606 that is communicatively coupled with the position actuator 602, deposition power supply 604, and electrode-array drivers 616. The system controller 606 can instruct the position actuator 602 to change the relative position of the printhead 610 and build plate 650. In the same or other examples, the system controller 606 can selectively instruct some electrode-array drivers 616 to provide current through a subset of pixelated electrodes 621 selected the set of pixelated electrodes 620 (e.g., based on the required deposition location).

During the operation, the ECAM system 600 also comprises electrolyte 680 comprising a source of cations (e.g., metal cations) that are reduced on build plate 650 (operable as a cathode during this operation) and form the material (e.g., copper deposit). More specifically, material (e.g., copper deposit) is deposited onto build plate 650 from the electrolyte 680 by flowing the electrical current between selected electrodes in the set of pixelated electrodes 620 and the build plate 650 as noted above. In some examples, further granularity is provided by controlling the current levels through each one of the electrode-array drivers 616. In other words, not only the current can be shut off through one or more electrode-array drivers 616 but different levels of current can flow through different electrode-array drivers 616 (and as a result through the corresponding electrodes in the set of pixelated electrodes 620).

Referring to FIG. 6B, a printhead 610 comprises a set of pixelated electrodes 620. These electrodes may be also referred to as microelectrodes (or micro-anodes), and/or pixels. This individually-addressable feature of the set of pixelated electrodes 620 allows the achievement of different deposition rates at different locations on build plate 650. The electrodes form a deposition grid, in which these electrodes may be offset relative to each other along the X-axis and Y-axis, each within a grid footprint. Rectangular grids may be characterized by a grid X-axis pitch (corresponding to the length of each grid region along the X-axis), grid Y-axis pitch (corresponding to the length of a grid region along the Y-axis), overall grid pitch (corresponding to the minimum of the grid X-axis pitch and the grid Y-axis pitch), and grid region area. In the same or other examples, one or both of the grid's X-axis pitch and the Y-axis pitch are 600 micrometers or less, 50 micrometers or less, or even 35 micrometers or less. Other example grids include triangular, hexagonal, or other patterns that partially or completely tessellate a surface. In some examples, the electrodes are formed/deposited from an insoluble conductive material, such as platinum group metals and their associated oxides, doped semiconducting materials, and carbon nanotubes. The shape of the electrodes can be round, rectangular, or other shapes. The area of the electrodes (the pixel size) is smaller (e.g., at least 6% smaller, at least 60% smaller, at least 20% smaller) than the grid footprint, thereby providing space between the electrodes. In some examples, the pitch is between 25 micrometers and 35 micrometers, while the pixel size is between 65 micrometers and 20 micrometers.

FIG. 6C is a schematic expanded view of a portion of ECAM system 600 illustrating electrolyte 680 between the printhead 610 and build plate 650, in accordance with some examples. FIG. 6D is a schematic block diagram illustrating different components of electrolyte 680. For example, electrolyte 680 may comprise salt 682, electrolyte solution solvent 686, and conductive agent 688. Salt comprises cations 683 and anions 684. Cations 683 can be in the form of metal ions, metal complexes, and the like. Some examples of cations 683 include metal cations (e.g., copper ions, nickel ions, tungsten ions, gold ions, silver ions, cobalt ions, chrome ions, iron ions, or tin ions), and other types of cations are within the scope. Some specific examples of salt 682 (feedstock ion sources) include but are not limited to copper sulfate, copper chloride, copper fluoroborate, copper pyrophosphate, nickel sulfate, nickel ammonium sulfate, nickel chloride, nickel fluoroborate, zinc sulfate, sodium thiocyanate, zinc chloride, ammonium chloride, sodium tungstate, cobalt chloride, cobalt sulfate, hydroxy acids, and aqua ammonia. In some examples, feedstock ion sources, or other sources of cations (e.g., salts) are referred to as material concentrates. Electrolyte solution solvent 686 can be water, which dissociates (2H2O(I)=>O2(g)+4H+(aq.)+4e−) on the electrodes that are activated during this operation. Specifically, the activated electrodes are connected to the deposition power supply. In some examples, electrolyte 680 comprises catholyte conductive agent 688, such as an acid (e.g., sulfuric acid, acetic acid, hydrochloric acid, nitric acid, hydrofluoric acid, boric acid, citric acid, and phosphoric acid). In some examples, electrolyte 680 comprises one or more additives, such as a leveler, a suppressor, and an accelerator, particulates for co-deposition (e.g., nanoparticles and microparticles such as diamond particles, tungsten-carbide particles, chromium-carbide particles, and silicon-carbide particles).

Returning to the example shown in FIG. 6D, cations (e.g., metal cations are combined with electrons, which are supplied to build plate 650 thereby forming the material (e.g., copper deposit). As noted above, the charge balance within electrolyte 680 is maintained by protons generated at the printhead 610. It should be noted that only a set of activated electrodes (illustrated in black color) can be activated during this ECAM process resulting in electrolytic deposit/material formed on a corresponding portion of build plate 650. This corresponding portion is aligned with the activated electrode while the remaining portion of electrodes (inactive electrodes) remains free of electrolytic deposit. This selective deposition is a core ECAM feature provided by selective control of the current passing through the activated electrodes.

Specifically, in some examples, an ECAM system 600 comprises a build plate 650 and a printhead 610 comprising a set of pixelated electrodes 620 and electrode-array drivers 616, such that each of the electrode-array drivers 616 is configured to control a current flow through a corresponding electrode in the set of pixelated electrodes 620. The ECAM system 600 also comprises a position actuator 602 for controlling the position of the build plate 650 relative to the printhead 610 and a power supply 604 connected to the build plate 650 and each of the electrode-array drivers 616. Furthermore, the ECAM system 600 comprises a system controller 606 communicatively coupled to each of the electrode-array drivers 616, the position actuator 602, and the power supply 604. The system controller 606 is configured to store various deposition parameters, e.g., which are developed based on the configuration of the multiphase heat exchanger 100. During this operation, a subset of pixelated electrodes 621 is selectively activated from the set of pixelated electrodes 620 according to the deposition parameters thereby causing an ionic flow through an electrolyte 680 provided between at least the subset of pixelated electrodes 621 and the printhead 610. Furthermore, the system controller 606 is configured to (c) instruct the power supply 604 and the electrode-array drivers 616 to map the deposited layer 655 by applying a mapping voltage to each pixelated electrode in the subset of pixelated electrodes 621 and monitoring a current through each pixelated electrode in the subset of pixelated electrodes 621. In some examples, such a mapping process may be used to register the horizontal (left, right) position of the build plate 650 relative to the printhead 610 based on the shape and/or features of the build plate 650. As noted elsewhere, the current through each pixelated electrode in the subset of pixelated electrodes 621 depends on a vertical positional relationship (e.g., the gap) between each pixelated electrode in the subset of pixelated electrodes 621 and the deposited layer 655.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present embodiments are to be considered illustrative and not restrictive.

1. A method of fabricating a multiphase heat exchanger for use on a heat source comprising a heat-transferring surface using electrochemical additive manufacturing (ECAM), the method comprising:
submerging a build plate comprising a deposition surface into an electrolyte, wherein the build plate comprises a base surface formed by at least one of (a) an evaporator base, (b) a condenser base, or (c) a liquid-return base;
submerging a printhead into the electrolyte proximate to the deposition surface, the printhead comprises a set of pixelated electrodes and electrode-array drivers; and
selectively activating an electrode subset from the set of pixelated electrodes using the electrode-array drivers thereby generating an ionic flow through the electrolyte between the electrode subset and a portion of the deposition surface aligned with the electrode subset and thereby electrochemically depositing wicking structures on the base surface of the build plate, wherein any two adjacent ones of the wicking structures, attached to the evaporator base, are spaced apart by an average pitch selected to maintain a heat-transfer fluid, in a liquid phase, in contact with the at least one of the evaporator base during operation of the multiphase heat exchanger.

2. The method of claim 1, wherein the base surface is formed by the evaporator base such that depositing the wicking structures on the base surface forms an evaporator configured to evaporate the heat-transfer fluid, from a liquid phase to a gas phase, upon receiving heat from the heat source.

3. The method of claim 2, wherein the base surface is formed by the condenser base such that depositing the wicking structures on the base surface forms a condenser configured to condense the heat-transfer fluid, from the gas phase to the liquid phase.

4. The method of claim 3, wherein the base surface is formed by the liquid-return base such that depositing the wicking structures on the base surface forms a liquid-return portion is configured to return the heat-transfer fluid, in the liquid phase, from the condenser to the evaporator.

5. The method of claim 1, further comprising thermally coupling the evaporator base to the heat-transferring surface of the heat source.

6. The method of claim 5, wherein thermally coupling the evaporator base to the heat-transferring surface of the heat source comprises positioning a thermal interface between the evaporator base and the heat-transferring surface.

7. The method of claim 1, wherein the build plate comprises the heat source.

8. The method of claim 7, wherein the heat source is selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC).

9. The method of claim 7, further comprising, prior to submerging the build plate into the electrolyte, method comprises forming a conductive seed layer on the build plate.

10. The method of claim 9, wherein forming the conductive seed layer on the build plate comprises one or more techniques selected from the group consisting of sputtering, electroless electroplating, and thermal bonding.

11. The method of claim 1, further comprising, prior to selectively activating the electrode subset, designing a shape of the multiphase heat exchanger and developing a set of deposition maps corresponding to the shape of the multiphase heat exchanger, wherein the electrode subset is activated based on a deposition map in the set of deposition maps.

12. The method of claim 1, further comprising, after submerging the build plate and submerging the printhead and before selectively activating the electrode subset, registering a horizontal position of the build plate relative to the printhead using a mapping process and based on a shape of the build plate.

13. The method of claim 1, further comprising replacing the electrolyte between the printhead and the build plate.

14. The method of claim 13, wherein the electrolyte is replaced with the electrolyte having a different composition.

15. The method of claim 1, further comprising attaching an external heat-transferring unit to a condenser base.

16. The method of claim 15, wherein attaching the external heat-transferring unit to the condenser base comprises:
submerging the condenser base into the electrolyte, and
selectively activating the electrode subset from the set of pixelated electrodes using the electrode-array drivers thereby electrochemically depositing the external heat-transferring unit comprising heat-transferring structures extending away from the condenser base in a direction opposite of the evaporator base.

17. The method of claim 1, wherein:
the condenser base is spaced away from the evaporator base by a cavity,
the method further comprises filing the cavity with the heat-transfer fluid selected from the group consisting of a hydrofluorocarbon refrigerant, a hydrocarbon refrigerant, a chlorofluorocarbon refrigerant, an ammonia refrigerant, and a carbon dioxide refrigerant.

18. The method of claim 1, wherein one or more of the wicking structures are selected from the group consisting of a composite wick, a lattice, a TPMS structure, a uniform and composite structure, a composite gyroid, a body-centered-cubic (BCC), and a composite body-centered-cubic (BCC).

19. The method of claim 1, wherein the wicking structures, attached to the condenser base, are configured to enhance capillary pumping of the heat-transfer fluid, in the liquid phase, away from the condenser base.

20. The method of claim 1, wherein the wicking structures, attached to the liquid-return base, vary in size or pitch along a direction from the condenser base to the evaporator base to compensate for changes in a gravitational or capillary head.
